(19) United States
(12) Patent Application Publication
(10) Pub. No.: US 2010/0192046 A1
(43) Pub. Date: Jul. 29, 2010

(54) CHANNEL ENCODING

(75) Inventors: Martial Gander, Les Arcs Sur Argens (FR); Olivier A. H. Masse, Grasse (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/814,072

(22) PCT Filed: Dec. 29, 2005
(86) PCT No.: PCT/IB05/54421

§ 371 Date: Apr. 9, 2010

(30) Foreign Application Priority Data
Jan. 14, 2005 (EP) 05300035.2
Dec. 29, 2005 (IB) PCT/IB2005/054421

(51) Int. Cl. H03M 13/23; G06F 11/10

(52) U.S. Cl. 714/786; 714/E11.032

(57) ABSTRACT

A channel encoding method of calculating, using a programmable processor, a code identical with a code obtained with a hardware channel encoder. The method comprises:—a first step (112, 120; 222) of reading the result of a first sub-system of parallel XOR operations between shifted bits in a first pre-computed lookup table at a memory address determined from the value of the inputted bits, the first pre-computed lookup table storing any possible result of the first sub-system at respective memory addresses, and—at least a step (116, 124; 226) of carrying out an XOR operation between the read result and the result of a second sub-system of parallel XOR operations using an XOR instruction of the programmable processor.

### FIELD OF THE INVENTION

The present invention relates to channel encoding

### BACKGROUND OF THE INVENTION

Hardware channel encoders may include the following elements to generate a code:
a shift register to shift an inputted set of bits by one bit, and
XOR gates to carry out XOR operations between the shifted bits.

Some channel encoding methods which calculate a code identical with a code obtained with such a hardware channel encoder are implemented with programmable processors. These methods read the code in one pre-computed lookup table at a memory address determined from the inputted set of bits.

The size of the lookup table is proportional to 2^{n+k}, where n is the number of inputted bits processed in parallel and k is an integer also known as the constraint length.

For example, WO 03/52997 (in the name of HURT James Y et al.) discloses such a method.

The size of the lookup table is important and therefore the method requires a large memory space, which is not always available on portable user equipment such as mobile phones.

### SUMMARY OF THE INVENTION

Accordingly, it is an object of the invention to provide a channel encoding method designed to be implemented with a programmable processor, which requires less memory space.

The invention provides a channel encoding method designed to be implemented with a programmable processor capable of executing XOR operations in response to XOR instructions, wherein the method comprises:
a first step of reading the result of a first sub-system of parallel XOR operations between shifted bits in a first pre-computed lookup table at a memory address determined from the value of the inputted bits, the first pre-computed lookup table storing any possible result of the first sub-system at respective memory addresses, and
at least a step of carrying out an XOR operation between the read result and the result of a second sub-system of parallel XOR operations using the XOR instruction of the programmable processor.

The above method mixes computation of XOR operations by using a lookup table and by using XOR instructions. Therefore, on the one hand, the size of the lookup table is smaller than with a conventional channel encoding method using no XOR instructions. On the other hand, the number of XOR instructions used to compute the code is smaller than with a channel encoding method using no lookup table. As a result, this method is well-suited to implement on portable user equipment having little memory space or on base stations.

The features of claim 2 reduce the number of operations to be performed by the processor.

The features of claim 3 reduce the memory space necessary to implement a convolutional encoding method on a programmable processor.

The features of claim 4 reduce the memory space necessary to implement a channel encoding method corresponding to a hardware channel encoder having at least a feedback chain, e.g., a turbo encoder.

The features of claim 5 reduce the memory space necessary to implement the channel encoding method on a programmable processor.

The features of claim 6 reduce the number of operations to be performed by the processor because it is not necessary to carry out multiplexing operations.

The invention also relates to a memory and a processor program to execute the above channel encoding method as well as to a channel encoder, user equipment and a base station implementing the method.

These and other aspects of the invention will be apparent from the following description, drawings and claims.

### BRIEF DESCRIPTION OF THE DRAWINGS

FIG. 1 is a schematic diagram of a hardware turbo encoder;

FIG. 2 is a schematic diagram of a forward chain of the turbo encoder of FIG. 1;

FIG. 3 is a schematic diagram of a feedback chain of the turbo encoder of FIG. 1;

FIG. 4 is a schematic diagram of user equipment having a programmable processor which executes a channel encoding method;

FIG. 5 is a flowchart of a channel encoding method implemented in the user equipment of FIG. 4;

FIG. 6 is a schematic diagram of a hardware convolutional encoder;

FIG. 7 is a schematic diagram of user equipment having a programmable processor to execute a convolutional encoding method; and

FIG. 8 is a flowchart of a convolutional encoding method implemented in the user equipment of FIG. 7.

### DESCRIPTION OF THE PREFERRED EMBODIMENTS

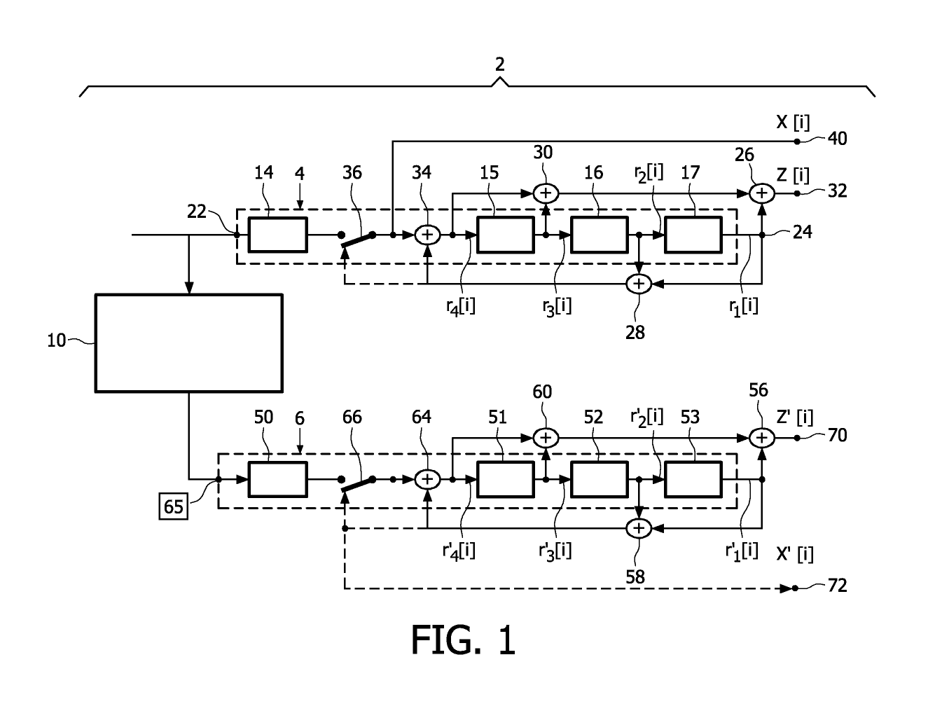

FIG. 1 shows a hardware turbo encoder 2. For simplicity, only the details necessary to understand the invention are shown in FIG. 1.

More details on the element of encoder 2 may be found in 3G wireless standards such as 3GPP (3^{rd} Generation Partnership Project) UTRA TDD/FDD and 3GPP2 CDMA2000.

Like any channel encoder, turbo encoder 2 is designed to add redundancy in an inputted bit stream. For example, encoder 2 outputs three bits X[i], Z[i] and Z′[i] for each bit dᵢ of the inputted bit stream. Index i represents the instant at which bit dᵢ is inputted in encoder 2. Index i is equal to zero when the first bit d₀ is inputted and is incremented by one each time a new bit is inputted. Typically, the instant at which a bit dᵢ is inputted in encoder 2 corresponds to the raising edge of a clock signal.

Encoder 2 has two identical left feedback shift registers 4 and 6 and one interleaver 10.

Shift register 4 includes four memory elements 14 to 17 connected in series. Memory element 14 is connected to an input 22 to receive new bits dᵢ and memory element 17 is connected to an output 24. Output 24 is connected to the first inputs of two XOR gates 26 and 28. The second input of XOR gate 26 is connected to an output of a XOR gate 30.

The second input of XOR gate 28 is connected at an output of memory element 16.

An output of XOR gate 26 is connected to a terminal 32 to output bit Z[i].

An output of XOR gate 28 is connected to a first input of XOR gate 34. A second input of XOR gate 34 is connected to an output of memory element 14 through a two-position switch 36.

An output of XOR gate 34 is connected to an input of memory element 15 and to a second input of XOR gate 30.

In a first position, switch 36 connects the output of memory element 14 to the second input of XOR gate 34.

In a second position, switch 36 connects the output of XOR gate 28 to the second input of XOR gate 34.

Switch 36 is shifted to the second position only to encode the end of an inputted bit stream. This connection is represented in a dashed line.

The second input of XOR gate 34 is also connected to a terminal 40 to output bit X[i].

Each memory element is intended to store one bit and to shift this bit to the next memory element at each instant i.

The value of bits r₄[i], r₃[i], r₂[i] and r₁[i] of a remainder r are stored in shift register 4.

The values of bits r₄[i], r₃[i], r₂[i] and r₁[i] are equal to the value of signals at the inputs of memory elements 15, 16 and 17 and at the output of memory element 17, respectively. The remainder value is a function of the values of the inputted bits dᵢ and of the previous bits r₄[I−1], r₃[I−1], r₂[I−1] and r₁ [I−1].

Shift register 6 also includes four memory elements 50-53 connected in series.

The connection of memory elements 50-53 to each other is identical with the connection of memory elements 14-17 and will not be described in detail. The connections between memory elements 50-53 also use four XOR gates 56, 58, 60 and 64 and one switch 66 corresponding to XOR gates 26, 28, 30 and 34 and switch 36, respectively.

Shift register 6 is connected to two terminals 70 and 72. Terminal 70 is connected to the output of XOR gate 56 to output bit Z′[i]. Terminal 72 is connected to the output of XOR gate 58 to output a bit X′[i] at the end of the encoding of the bit stream. This connection is represented in a dashed line.

The set of bits r′₄[i], r′₃[i], r′₂[i] and r′₁[i] of a remainder r′ is stored in shift register 6.

The values of bits r′₄[i], r′₃[i], r′₂[i] and r′₁[i] are equal to the values of the signals at the inputs of memory elements 51, 52 and 53 and at the output of memory element 53. The value of remainder r′ is a function of the values of inputted bits eᵢ and of the previous value of bits r′₄[I−1], r′₃[I−1], r′₂[I−1] and r′₁[I−1].

Memory element 50 has an input 65 to receive bits eᵢ.

Interleaver 10 has an input connected to input 22 and an output connected to input 65. Interleaver 10 mixes bits dᵢ from the inputted bit stream and outputs a mixed bit stream made of bits eᵢ.

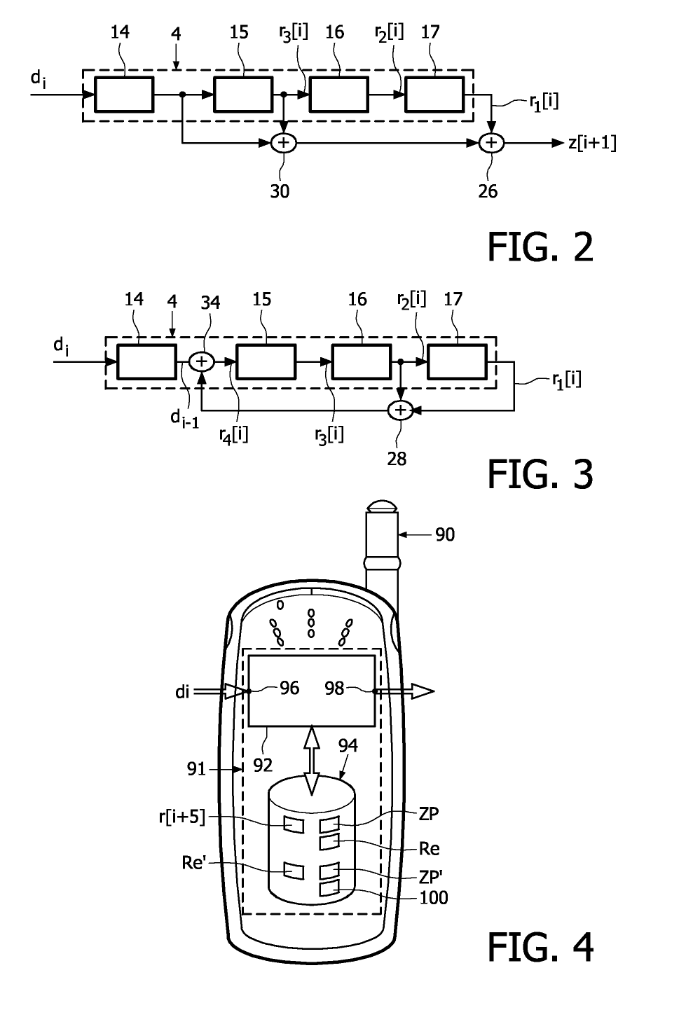

FIGS. 2 and 3 show details of encoder 2. In FIGS. 2 and 3, the elements already described in FIG. 1 have the same references.

FIG. 2 shows a forward chain of encoder 2. The forward chain includes XOR gates 26 and 30. Output bits Z[i] of the forward chain at instant i can be computed with the following relation:

Z[i]=r₄[i]⊕r₃[i]⊕r₁[i] (1)

where the symbol ⊕ is an XOR operation.

FIG. 3 shows in more detail a feedback chain of encoder 2. The feedback chain shown includes XOR gates 28 and 34. This feedback chain corresponds to the following relation:

r₄[i]=dᵢ₋₁⊕r₂[i]⊕r₁[i] (2)

The following relations can also be derived from the schematic diagram of encoder 2:

r₃[i]=r₄[i−1]

r₂[i]=r₃[i−1]

r₁[i]=r₂[i−1] (3)

The following system Z of parallel XOR operations is derived from relation (1) to calculate in parallel five successive output bits Z[i] to Z[i+4]:

$$Z = \{ \begin{matrix}Z [ i ] = {r}_{4} [ i ] ⊕ {r}_{3} [ i ] ⊕ {r}_{1} [ i ] \\ Z [ i + 1 ] = {r}_{4} [ i + 1 ] ⊕ {r}_{3} [ i + 1 ] ⊕ {r}_{1} [ i + 1 ] \\ Z [ i + 2 ] = {r}_{4} [ i + 2 ] ⊕ {r}_{3} [ i + 2 ] ⊕ {r}_{1} [ i + 2 ] \\ Z [ i + 3 ] = {r}_{4} [ i + 3 ] ⊕ {r}_{3} [ i + 3 ] ⊕ {r}_{1} [ i + 3 ] \\ Z [ i + 4 ] = {r}_{4} [ i + 4 ] ⊕ {r}_{3} [ i + 4 ] ⊕ {r}_{1} [ i + 4 ]\end{matrix} \qquad ( 4 )$$

Using relations (2) and (3), it is possible to write system Z using only the bits of the remainder r at instant i:

$$Z = \{ \begin{matrix}Z [ i ] = {d}_{i - 1} ⊕ {r}_{2} [ i ] ⊕ {r}_{3} [ i ] \\ Z [ i + 1 ] = {d}_{i} ⊕ {d}_{i - 1} ⊕ {r}_{3} [ i ] ⊕ {r}_{2} [ i ] ⊕ {r}_{1} [ i ] \\ Z [ i + 2 ] = {d}_{i + 1} ⊕ {d}_{i} ⊕ {d}_{i - 1} ⊕ {r}_{1} [ i ] ⊕ {r}_{3} [ i ] \\ Z [ i + 3 ] = {d}_{i + 2} ⊕ {d}_{i + 1} ⊕ {d}_{i} ⊕ {d}_{i - 1} ⊕ {r}_{1} [ i ] \\ Z [ i + 4 ] = {d}_{i + 3} ⊕ {d}_{i + 2} ⊕ {d}_{i + 1} ⊕ {d}_{i} ⊕ {r}_{2} [ i ]\end{matrix} \qquad ( 5 )$$

Thus, according to relation (5) bits Z[i] to Z[i+4] can be computed from the set of bits [dᵢ₋₁, . . . , dᵢ₊₃] and from the value of bits r₁[i], r₂[i] and r₃[i] at instant i.

A system r[i+5] to calculate in parallel the value of bits r₁[I+5], r₂[I+5] and r₃[I+5] at instant i+5 from the values of bits r₁[i], r₂[i] and r₃[i] at instant i can be derived from relations (2) and (3). System r[i+5] is as follows:

$$r ( i + 5 ) = \{ \begin{matrix}{r}_{3} [ i + 5 ] = {d}_{i + 3} ⊕ {d}_{i + 1} ⊕ {d}_{i} ⊕ {d}_{i - 1} ⊕ {r}_{1} [ i ] \\ {r}_{2} [ i + 5 ] = {d}_{i + 2} ⊕ {d}_{i} ⊕ {d}_{i - 1} ⊕ {r}_{3} [ i ] ⊕ {r}_{1} [ i ] \\ {r}_{1} [ i + 5 ] = {d}_{i + 1} ⊕ {d}_{i - 1} ⊕ {r}_{3} [ i ] ⊕ {r}_{2} [ i ] ⊕ {r}_{1} [ i ]\end{matrix} \qquad ( 6 )$$

From the schematic diagram of FIG. 1, a system X to compute in parallel bits X[i] to X[i+4] can be written as follows:

$$X = \{ \begin{matrix}X [ i ] = {d}_{i - 1} \\ X [ i + 1 ] = {d}_{i} \\ X [ i + 2 ] = {d}_{i + 1} \\ X [ i + 3 ] = {d}_{i + 2} \\ X [ i + 4 ] = {d}_{i + 3}\end{matrix} \qquad ( 7 )$$

In a similar way, a system Z′ of parallel XOR operations to calculate in parallel bits Z′[i] to Z′[i+4] from the value of a set of bits {eᵢ₋₁; . . . ; eᵢ₊₃} and the values of bits r′₁[i], r′₂[i], and r′₃[i] can be derived from FIG. 1. System Z is as follows:

$${Z}^{′} = \{ \begin{matrix}{Z}^{′} [ i ] = {e}_{i - 1} ⊕ {r}_{2}^{′} [ i ] ⊕ {r}_{3}^{′} [ i ] \\ {Z}^{′} [ i + 1 ] = {e}_{i} ⊕ {e}_{i - 1} ⊕ {r}_{3}^{′} [ i ] ⊕ {r}_{2}^{′} [ i ] ⊕ {r}_{1}^{′} [ i ] \\ {Z}^{′} [ i + 2 ] = {e}_{i + 1} ⊕ {e}_{i} ⊕ {e}_{i - 1} ⊕ {r}_{1}^{′} [ i ] ⊕ {r}_{3}^{′} [ i ] \\ {Z}^{′} [ i + 3 ] = {e}_{i + 2} ⊕ {e}_{i + 1} ⊕ {e}_{i} ⊕ {e}_{i - 1} ⊕ {r}_{1}^{′} [ i ] \\ {Z}^{′} [ i + 4 ] = {e}_{i + 3} ⊕ {e}_{i + 2} ⊕ {e}_{i + 1} ⊕ {e}_{i} ⊕ {r}_{2}^{′} [ i ]\end{matrix} \qquad ( 8 )$$

Similarly, system r′ [i+5] of parallel XOR operations to calculate in parallel bits r′₁[i+5], r′₂[i+5] and r′₃[i+5] is derived from FIG. 1. System r′[i+5] is as follows:

$${r}^{′} ( i + 5 ) = \{ \begin{matrix}{r}_{3}^{′} [ i + 5 ] = {e}_{i + 3} ⊕ {e}_{i + 1} ⊕ {e}_{i} ⊕ {e}_{i - 1} ⊕ {r}_{1}^{′} [ i ] \\ {r}_{2}^{′} [ i + 5 ] = {e}_{i + 2} ⊕ {e}_{i} ⊕ {e}_{i - 1} ⊕ {r}_{3}^{′} [ i ] ⊕ {r}_{1}^{′} [ i ] \\ {r}_{1}^{′} [ i + 5 ] = {e}_{i + 1} ⊕ {e}_{i - 1} ⊕ {r}_{3}^{′} [ i ] ⊕ {r}_{2}^{′} [ i ] ⊕ {r}_{1}^{′} [ i ]\end{matrix} \qquad ( 9 )$$

System Z can be pre-computed for any possible value of the set of bits {dᵢ₋₁; . . . ; dᵢ₊₃} and bit values r₁[i], r₂[i], r₃[i] and the results stored in a lookup table Z. Thus, lookup table Z contains 2⁸×5 bits. In a similar way, the results of system r[i+5], system Z′, and system r′[i+5] can be pre-computed for any possible set of inputted bits and any possible remainder value. As a result, implementing a turbo encoding method using lookup tables for systems Z, r[i+5], Z′ and r′[i+5] requires a memory storing 2⁸×5+2⁸×3+2⁸×5+2⁸×3 bits.

The result of system X can be read directly from the received bit dᵢ.

This memory space can be too large to store these lookup tables in user equipment such as a mobile phone. The following part of the description explains how it is possible to reduce the size of the lookup tables.

System Z can be split up into two sub-systems ZP and Rₑ because XOR operations are interchangeable:

Z=ZP⊕Rₑ (10)

where

$$\begin{matrix}ZP = \{ \begin{matrix}ZP [ i ] = {d}_{i - 1} \\ ZP [ i + 1 ] = {d}_{i} ⊕ {d}_{i - 1} \\ ZP [ i + 2 ] = {d}_{i + 1} ⊕ {d}_{i} ⊕ {d}_{i - 1} \\ ZP [ i + 3 ] = {d}_{i + 2} ⊕ {d}_{i + 1} ⊕ {d}_{i} ⊕ {d}_{i - 1} \\ ZP [ i + 4 ] = {d}_{i + 3} ⊕ {d}_{i + 2} ⊕ {d}_{i + 1} ⊕ {d}_{i}\end{matrix} & ( 11 ) \\ {R}_{e} = \{ \begin{matrix}{R}_{e} [ i ] = ⊕ {r}_{2} [ i ] ⊕ {r}_{3} [ i ] \\ {R}_{e} [ i + 1 ] = ⊕ {r}_{3} [ i ] ⊕ {r}_{2} [ i ] ⊕ {r}_{1} [ i ] \\ {R}_{e} [ i + 2 ] = ⊕ {r}_{1} [ i ] ⊕ {r}_{3} [ i ] \\ {R}_{e} [ i + 3 ] = ⊕ {r}_{1} [ i ] \\ {R}_{e} [ i + 4 ] = {r}_{2} [ i ]\end{matrix} & ( 12 )\end{matrix}$$

The value of sub-system ZP can be computed beforehand using only the value of the set of bits {dᵢ₋₁; . . . ; dᵢ₊₃} and sub-system Rₑ can be computed using only the value of remainder r[i]. Thus, a lookup table ZP comprising all the results of sub-system ZP for any possible value of the set of bits {dᵢ₋₁; . . . ; dᵢ₊₃} comprises only 2⁵−5 bits. Each result of sub-system ZP is stored at a respective memory address determined from the value of the set of bits {dᵢ₋₁; . . . ; dᵢ₊₃}.

A lookup table Rₑ comprising the results of sub-system Rₑ for any possible value of remainder r[i] stores only 2³−5 bits. In table Rₑ, each result of sub-system Rₑ is stored at a respective memory address determined from the value of bits r₁[i], r₂[i], r₃[i].

Therefore, using two lookup tables ZP and Rₑ instead of lookup table Z reduces the memory space necessary to implement the turbo encoding method.

In a similar way, the result of system Z′ can be computed from the result of two sub-systems ZP′ and Rₑ′ using the following relation:

Z′=ZP′⊕Rₑ′ (13)

where:

$$\begin{matrix}{ZP}^{′} = \{ \begin{matrix}{ZP}^{′} [ i ] = {e}_{i - 1} \\ {ZP}^{′} [ i + 1 ] = {e}_{i} ⊕ {e}_{i - 1} \\ {ZP}^{′} [ i + 2 ] = {e}_{i + 1} ⊕ {e}_{i - 1} \\ {ZP}^{′} [ i + 3 ] = {e}_{i + 2} ⊕ {e}_{i + 1} ⊕ {e}_{i} ⊕ {e}_{i - 1} \\ {ZP}^{′} [ i + 4 ] = {e}_{i + 3} ⊕ {e}_{i + 2} ⊕ {e}_{i + 1} ⊕ {e}_{i}\end{matrix} & ( 14 ) \\ {R}_{e}^{′} = \{ \begin{matrix}{R}_{e}^{′} [ i ] = ⊕ {r}_{2}^{′} [ i ] ⊕ {r}_{3}^{′} [ i ] \\ {R}_{e}^{′} [ i + 1 ] = {r}_{3}^{′} [ i ] ⊕ {r}_{2}^{′} [ i ] ⊕ {r}_{1}^{′} [ i ] \\ {R}_{e}^{′} [ i + 2 ] = {r}_{1}^{′} [ i ] ⊕ {r}_{3}^{′} [ i ] \\ {R}_{e}^{′} [ i + 3 ] = {r}_{1}^{′} [ i ] \\ {R}_{e}^{′} [ i + 4 ] = {r}_{2}^{′} [ i ]\end{matrix} & ( 15 )\end{matrix}$$

The pre-computed results of system ZP′ for each value of the set of bits {eᵢ₋₁; . . . ; eᵢ₊₃} are stored in a lookup table ZP′ and the results of sub-system Rₑ′ for any possible value of remainder r′[i] are stored in a lookup table Rₑ′.

The values of bits X[i] to X[i+4] are read from the values of the set of bits {dᵢ₋₁; . . . ; dᵢ₊₃}.

FIG. 4 shows user equipment 90 including channel encoder 91 having a programmable microprocessor 92 and a memory 94.

User equipment 90 is, for example, a mobile phone.

Microprocessor 92 has an input 96 to receive the stream of bits dᵢ and an output 98 to output a turbo encoded bit stream.

Memory 94 stores lookup table ZP, Rₑ, r[i+5], ZP′ and Re′. Lookup table r′[i+5] is identical with lookup table r[i+5] and only this last lookup table is stored in memory 94.

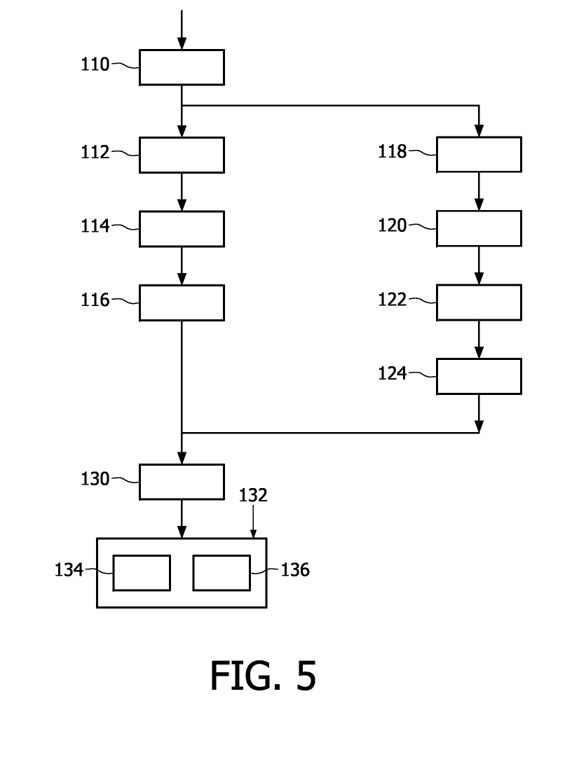

Microprocessor 92 is adapted to execute a microprocessor program 100 stored, for example, in memory 94. Program 100 includes instructions for the execution of the turbo encoding method of FIG. 5. Processor 92 is adapted to execute an XOR operation in response to an XOR instruction stored in memory 94.

The operation of processor 92 will now be described with reference to FIG. 5.

Initially, all the remainders r and r′ are null.

In step 110, processor 92 receives the first set of bits {d₀; . . . ; d₄}. Then, in step 112, processor 92 reads in parallel the bit values X[1] to X[5] and ZP[1] to ZP[5] in lookup table ZP at the memory address determined from the value of the set of bits {d₀; . . . ; d₄}.

In step 114, processor 92 also reads in parallel bits Rₑ[1] to Rₑ[5] in lookup table Rₑ at the memory address determined from the values of bits r₃[1], r₂[1] and r₁[1] which are all null.

Subsequently, in step 116, processor 92 carries out an XOR operation between the result of sub-system ZP read in step 112 and the result of sub-system Rₑ read in step 114 to obtain the value of bits Z[1] to Z[5] according to relation (10).

Parallel to steps 112-116, in step 118, processor 92 interleaves the received bits to generate the interleaved bit stream eᵢ.

Thereafter, in step 120, the values of bits ZP′[1] to ZP′[5] are read in parallel in lookup table ZP′ at the memory address determined from the value of the set of bits {e₀; . . . ; c₄}.

In step 122, processor 92 reads in parallel the values of bits Rₑ′[1] to Rₑ′[4] in lookup table Re′ using the values of bits r′₃[1], r′₂[1] and r′₁[1], which are all null. Then, in step 124, processor 92 carries out an XOR operation between the results read in steps 120 and 122 to obtain the values of bits Z′[1] to Z′[5] according to relation (13).

Once the values of bits X[1] to X[5]; Z[1] to Z[5] and Z′[1] to Z′[5] are known, in step 130, processor 92 combines these bit values to generate the turbo encoded bit stream outputted through output 98. The turbo encoded bit stream includes the bit values in the following order X[i], Z[i], Z′[i], X[i+1], Z[i+1], Z′[i+1], . . . and so on.

Thereafter, in step 132, processor 92 reads the values of remainder r and r′ necessary for the next iteration of steps 114 and 122 in lookup table r[i+5]. More precisely, during operation 134, processor 92 reads in parallel the values of bits r₁[6], r₂[6] and r₃[6] in lookup table r[i+5] at the memory address determined from the value of bits r₃[1], r₂[1] and r₁[1] and bits d₀ to d₄. In operation 136, microprocessor 92 reads in parallel the next values of bits r′₁[6], r′₂[6], r′₁[6] necessary for the next iteration of step 122 in lookup table r[i+5] at the memory address determined from the values of bits r′₃[1], r′₂[1] and r′₁[1].

Then, microprocessor 92 returns to step 110 to receive the next five bits dᵢ of the inputted bit stream.

Steps 112 to 132 are then repeated using the received new set of bits and the calculated new value for remainder r and r′.

The method of FIG. 5 when implemented in a programmable microprocessor like microprocessor 92, allows to compute a turbo encoded bit streamidentical with the one generated by the hardware turbo encoder 2.

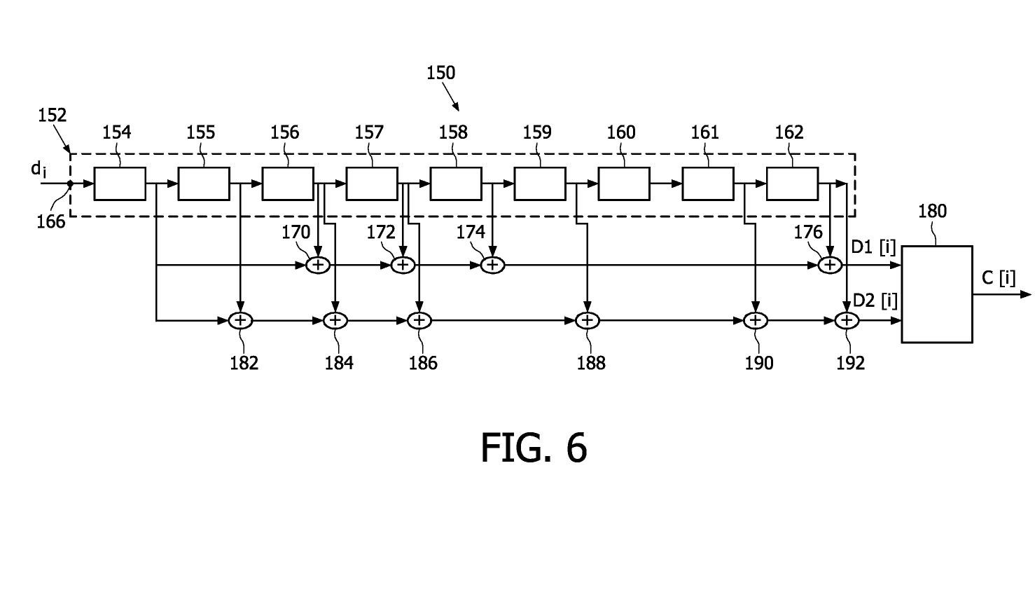

FIG. 6 shows a hardware convolutional encoder 150 which is another example of a hardware channel encoder. More precisely, encoder 150 is a convolutional encoder having a rate of 1/2. A rate of 1/2 means that for each bit dᵢ of the inputted bit stream, encoder 150 generates two bits of the encoded bit stream.

FIG. 6 shows only the details necessary to understand the invention. More details on such a convolutional encoder may be found in 3G wireless standards such as 3GPP UTRA TDD/FDD and 3GPP2 CDMA2000 previously cited.

Encoder 150 includes a shift register 152 having nine memory elements 154 to 162 connected in series. Element 154 has an input 166 to receive bits dᵢ of the input bit stream to be encoded.

Encoder 150 has two forward chains. The first forward chain is built using XOR gates 170, 172, 174 and 176 and outputs a bit D1[i] at instant i.

XOR gate 170 has one input connected to an output of memory element 154 and a second input connected to the output of memory element 156. XOR gate 170 has also an output connected to the first input of XOR gate 172. A second input of XOR gate 172 is connected to an output of memory element 156. An output of XOR gate 172 is connected to a first input of XOR gate 174. A second input of XOR gate 174 is connected to an output of memory element 158. An output of XOR gate 174 is connected to a first input of XOR gate 176. A second input of XOR gate 176 is connected to an output of memory element 162. An output of XOR gate 176 outputs bit D1[i] and is connected to a first input of a multiplexer 180.

The second forward chain is built using XOR gates 182, 184, 186, 188, 190 and 192.

XOR gate 182 has two inputs connected to the output of memory elements 154 and 155, respectively.

XOR gate 184 has two inputs connected to an output of XOR gate 182 and the output of memory element 156, respectively.

XOR gate 186 has two inputs connected to an output of XOR gate 184 and the output of memory element 157, respectively.

XOR gate 188 has two inputs connected to an output of XOR gate 186 and an output of memory element 159, respectively.

XOR gate 190 has two inputs connected to an output of XOR gate 188 and to an output of memory element 161, respectively.

XOR gate 192 has two inputs connected to an output of XOR gate 190 and to the output of memory element 162, respectively. XOR gate 192 has also an output to generate a bit D2[i], which is connected to a second input of multiplexer 180.

Multiplexer 180 converts bit D1[i] and D2[i] received in parallel on its inputs into a serial bit stream alternating the bit D1[i] and D2[i] generated by the two forward chains.

Sixteen consecutive output bits of the encoded output bit stream can be computed in parallel using a system D as follows:

$$D = \{ \begin{matrix}D 1 [ i ] = {d}_{i + 8} ⊕ {d}_{i + 6} ⊕ {d}_{i + 5} ⊕ {d}_{+ 4} ⊕ {d}_{i} \\ D 2 [ i ] = {d}_{i + 8} ⊕ {d}_{i + 7} ⊕ {d}_{i + 6} ⊕ {d}_{i + 5} ⊕ {d}_{i + 3} ⊕ {d}_{i + 1} ⊕ {d}_{i} \\ D 1 [ i + 1 ] = {d}_{i + 9} ⊕ {d}_{i + 7} ⊕ {d}_{i + 6} ⊕ {d}_{+ 5} ⊕ {d}_{i + 1} \\ D 2 [ i + 1 ] = {d}_{i + 9} ⊕ {d}_{i + 8} ⊕ {d}_{i + 7} ⊕ {d}_{i + 6} ⊕ {d}_{i + 4} ⊕ {d}_{i + 2} ⊕ {d}_{i + 1} \\ D 1 [ i + 2 ] = {d}_{i + 10} ⊕ {d}_{i + 8} ⊕ {d}_{i + 7} ⊕ {d}_{+ 6} ⊕ {d}_{i + 2} \\ D 2 [ i + 2 ] = {d}_{i + 10} ⊕ {d}_{i + 9} ⊕ {d}_{i + 8} ⊕ {d}_{i + 7} ⊕ {d}_{i + 5} ⊕ {d}_{i + 3} ⊕ {d}_{i + 2} \\ D 1 [ i + 3 ] = {d}_{i + 11} ⊕ {d}_{i + 9} ⊕ {d}_{i + 8} ⊕ {d}_{+ 7} ⊕ {d}_{i + 3} \\ D 2 [ i + 3 ] = {d}_{i + 11} ⊕ {d}_{i + 10} ⊕ {d}_{i + 9} ⊕ {d}_{i + 8} ⊕ {d}_{i + 6} ⊕ {d}_{i + 4} ⊕ {d}_{i + 3} \\ D 1 [ i + 4 ] = {d}_{i + 12} ⊕ {d}_{i + 10} ⊕ {d}_{i + 9} ⊕ {d}_{+ 8} ⊕ {d}_{i + 4} \\ D 2 [ i + 4 ] = {d}_{i + 12} ⊕ {d}_{i + 11} ⊕ {d}_{i + 10} ⊕ {d}_{i + 9} ⊕ {d}_{i + 7} ⊕ {d}_{i + 5} ⊕ {d}_{i + 4} \\ D 1 [ i + 5 ] = {d}_{i + 13} ⊕ {d}_{i + 11} ⊕ {d}_{i + 10} ⊕ {d}_{+ 9} ⊕ {d}_{i + 5} \\ D 2 [ i + 5 ] = {d}_{i + 13} ⊕ {d}_{i + 12} ⊕ {d}_{i + 11} ⊕ {d}_{i + 10} ⊕ {d}_{i + 8} ⊕ {d}_{i + 6} ⊕ {d}_{i + 5} \\ D 1 [ i + 6 ] = {d}_{i + 14} ⊕ {d}_{i + 12} ⊕ {d}_{i + 11} ⊕ {d}_{+ 10} ⊕ {d}_{i + 6} \\ D 2 [ i + 6 ] = {d}_{i + 14} ⊕ {d}_{i + 13} ⊕ {d}_{i + 12} ⊕ {d}_{i + 11} ⊕ {d}_{i + 9} ⊕ {d}_{i + 7} ⊕ {d}_{i + 6} \\ D 1 [ i + 7 ] = {d}_{i + 15} ⊕ {d}_{i + 13} ⊕ {d}_{i + 12} ⊕ {d}_{+ 11} ⊕ {d}_{i + 7} \\ D 2 [ i + 7 ] = {d}_{i + 15} ⊕ {d}_{i + 14} ⊕ {d}_{i + 13} ⊕ {d}_{i + 12} ⊕ {d}_{i + 10} ⊕ {d}_{i + 8} ⊕ {d}_{i + 7}\end{matrix} \qquad ( 16 )$$

System D shows that a block of 16 consecutive bits of the encoded output bit stream can be computed from the value of the set of bits {dᵢ; . . . ; dᵢ₊₁₅}. Note that system D carries out the multiplexing operation of multiplexer 180. It is also possible to pre-compute the results of system D for any possible value of the set of bits {dᵢ; . . . ; dᵢ₋₁₅} and to record each result in a lookup table D at a memory address determined from the value of the set of input bits {dᵢ; . . . ; dᵢ₊₁₅}. Lookup table D contains 2¹⁶×16 bits. The memory space used to implement a convolutional encoding method using system D can be reduced by splitting up system D into two sub-systems DP1 and DP2 as follows:

D=DP1⊕DP2 (17)

where:

$$\begin{matrix}DP 1 = \{ \begin{matrix}DP 1 [ i ] = {d}_{i + 6} ⊕ {d}_{i + 5} ⊕ {r}_{i + 4} ⊕ {d}_{i} \\ DP 1 [ i + 1 ] = {d}_{i + 7} ⊕ {d}_{i + 6} ⊕ {d}_{i + 5} ⊕ {d}_{i + 3} ⊕ {d}_{i + 1} ⊕ {d}_{i} \\ DP 1 [ i + 2 ] = {d}_{i + 7} ⊕ {d}_{i + 6} ⊕ {d}_{i + 5} ⊕ {d}_{i + 1} \\ DP 1 [ i + 3 ] = {d}_{i + 7} ⊕ {d}_{i + 6} ⊕ {d}_{i + 4} ⊕ {d}_{i + 2} ⊕ {d}_{i + 1} \\ DP 1 [ i + 4 ] = ⊕ {d}_{i + 7} ⊕ {d}_{i + 6} ⊕ {d}_{i + 2} \\ DP 1 [ i + 5 ] = {d}_{i + 7} ⊕ {d}_{i + 5} ⊕ {d}_{i + 3} ⊕ {d}_{i + 2} \\ DP 1 [ i + 6 ] = {d}_{i + 7} ⊕ {d}_{i + 3} \\ DP 1 [ i + 7 ] = {d}_{i + 6} ⊕ {d}_{i + 4} ⊕ {d}_{i + 3} \\ DP 1 [ i + 8 ] = {d}_{i + 4} \\ DP 1 [ i + 9 ] = {d}_{i + 7} ⊕ {d}_{i + 5} ⊕ {d}_{i + 4} \\ DP 1 [ i + 10 ] = {d}_{i + 5} \\ DP 1 [ i + 11 ] = {d}_{i + 6} ⊕ {d}_{i + 5} \\ DP 1 [ i + 12 ] = {d}_{i + 6} \\ DP 1 [ i + 13 ] = {d}_{i + 7} ⊕ {d}_{i + 6} \\ DP 1 [ i + 14 ] = {d}_{i + 7} \\ DP 1 [ i + 15 ] = {d}_{i + 7}\end{matrix} & ( 18 ) \\ DP 2 = \{ \begin{matrix}DP 2 [ i ] = {d}_{i + 8} \\ DP 2 [ i + 1 ] = {d}_{i + 8} \\ DP 2 [ i + 2 ] = {d}_{i + 9} \\ DP 2 [ i + 3 ] = {d}_{i + 9} ⊕ {d}_{i + 8} \\ DP 2 [ i + 4 ] = {d}_{i + 10} ⊕ {d}_{i + 8} \\ DP 2 [ i + 5 ] = {d}_{i + 10} ⊕ {d}_{i + 9} ⊕ {d}_{i + 8} \\ DP 2 [ i + 6 ] = {d}_{i + 11} ⊕ {d}_{i + 9} ⊕ {d}_{i + 8} \\ DP 2 [ i + 7 ] = {d}_{i + 11} ⊕ {d}_{i + 10} ⊕ {d}_{i + 9} ⊕ {d}_{i + 8} \\ DP 2 [ i + 8 ] = {d}_{i + 12} ⊕ {d}_{i + 10} ⊕ {d}_{i + 9} ⊕ {d}_{i + 8} \\ DP 2 [ i + 9 ] = {d}_{i + 12} ⊕ {d}_{i + 11} ⊕ {d}_{i + 10} ⊕ {d}_{i + 9} \\ DP 2 [ i + 10 ] = {d}_{i + 13} ⊕ {d}_{i + 11} ⊕ {d}_{i + 10} ⊕ {d}_{i + 9} \\ DP 2 [ i + 11 ] = {d}_{i + 13} ⊕ {d}_{i + 12} ⊕ {d}_{i + 11} ⊕ {d}_{i + 10} ⊕ {d}_{i + 8} \\ DP 2 [ i + 12 ] = {d}_{i + 14} ⊕ {d}_{i + 12} ⊕ {d}_{i + 11} ⊕ {d}_{i + 10} \\ DP 2 [ i + 13 ] = {d}_{i + 14} ⊕ {d}_{i + 13} ⊕ {d}_{i + 12} ⊕ {d}_{i + 11} ⊕ {d}_{i + 9} \\ DP 2 [ i + 14 ] = {d}_{i + 15} ⊕ {d}_{i + 13} ⊕ {d}_{i + 12} ⊕ {d}_{i + 11} \\ DP 2 [ i + 15 ] = {d}_{i + 15} ⊕ {d}_{i + 14} ⊕ {d}_{i + 13} ⊕ {d}_{i + 12} ⊕ {d}_{i + 10} ⊕ {d}_{i + 8}\end{matrix} & ( 19 )\end{matrix}$$

The results of sub-system DP1 can be pre-computed for each value of the set of bits {dᵢ; . . . ; dᵢ₊₇}. Each result of the pre-computation of sub-system DP1 is stored in a lookup table DP1 at an address determined from the corresponding value of the set of bits {dᵢ; . . . ; d₇}. Lookup table DP1 only includes 2⁸×16 bits.

Similarly, each result of sub-system DP2 can be stored in a lookup table DP2 at a memory address determined from the corresponding value of the set of bits {dᵢ₊₈; . . . ; dᵢ₊₁₅}.

Therefore, implementing the convolutional encoding method using lookup tables DP1 and DP2 instead of lookup table D, decreases the memory space necessary for this implementation.

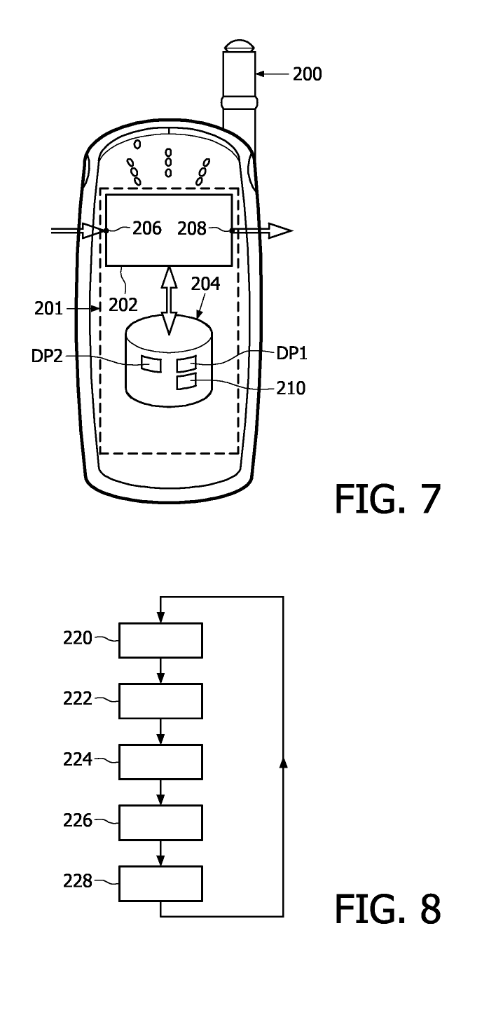

FIG. 7 shows user equipment 200 including a convolutional encoder 201 having a programmable microprocessor 202 connected to a memory 204.

For example, user equipment 200 is a mobile phone.

Microprocessor 202 has an input 206 to receive the bit stream to be encoded and an output 208 to output the encoded bit stream.

Processor 202 executes instructions stored in a memory, for example, in memory 204. Processor 202 is also adapted to execute an XOR operation in response to an XOR instruction.

Memory 204 stores a microprocessor program 210 having instructions for the execution of the method of FIG. 8 when executed by processor 202. Memory 204 also stores lookup tables DP1 and DP2.

The operation of microprocessor 202 will now be described with reference to FIG. 8.

Initially, in step 220, microprocessor 202 receives a new set of bits {dᵢ; . . . ; dᵢ₊₁₅}. Then, in step 222, microprocessor 202 reads in parallel in lookup table DP1 the values of bits DP1[i] to DP1[i+15] at a memory address only determined by the value of the set of bits {dᵢ; . . . ; dᵢ₊₇}.

Subsequently, in step 224, microprocessor 202 reads in parallel in lookup table DP2 the values of bits DP2[i] to DP2[i+15] at a memory address only determined by the value of the set of bits {dᵢ₊₈; . . . ; dᵢ₊₁₅}.

Thereafter, in step 226, microprocessor 202 carries out an XOR operation between the results of a sub-system DP1 and DP2 to calculate bits D1[i] to D1[i+7] and D2[i] to D2[i+7] according to relation (17).

In step 228, the encoded bits are outputted through output 208.

Then, steps 222-228 are repeated for the following set of bits {dᵢ₊₈; . . . ; dᵢ₊₂₃}.

Many additional embodiments are possible. For example, in the embodiment of FIG. 4, lookup table ZP′ is cancelled. In fact, the result of sub-system ZP′ can be read from lookup table ZP because lookup tables ZP and ZP′ are identical as far as the bits Z[i] to Z[i+4] are concerned. In a similar way, lookup table Rₑ′ in the embodiment of FIG. 4 is cancelled and the values of bits R′ₑ[i] to R′ₑ[i+4] are read from lookup table Rₑ because lookup tables Rₑ and Rₑ′ are identical. This further reduces the memory space necessary to implement the turbo encoding method.

Each sub-system r[i+5] or r′[i+5] can be split into two sub-systems, the values of the first sub-system depending only on the value of the set of bits {dᵢ₋₁; . . . ; dᵢ₊₃} or {ieᵢ₋₁; . . . ; eᵢ₊₃}, and the values of the second sub-system depending only on the value of the remainder r[i] or r′[i].

The memory space necessary to implement the above channel encoding method can be further reduced by splitting at least one of the sub-systems into at least two sub-systems. For example, sub-system DP1 can be split into two sub-systems DP11 and DP12, according to the following relation:

DP1=DP11⊕DP12 (20)

where:

$$\begin{matrix}DP 11 = \{ \begin{matrix}DP 11 [ i ] = {d}_{i} \\ DP 11 [ i + 1 ] = {d}_{i + 3} ⊕ {d}_{i + 1} ⊕ {d}_{i} \\ DP 11 [ i + 2 ] = {d}_{i + 1} \\ DP 11 [ i + 3 ] = {d}_{i + 2} ⊕ {d}_{i + 1} \\ DP 11 [ i + 4 ] = {d}_{i + 2} \\ DP 11 [ i + 5 ] = {d}_{i + 3} ⊕ {d}_{i + 2} \\ DP 11 [ i + 6 ] = {d}_{i + 3} \\ DP 11 [ i + 7 ] = {d}_{i + 3} \\ DP 11 [ i + 8 ] = Ø \\ DP 11 [ i + 9 ] = Ø \\ DP 11 [ i + 10 ] = Ø \\ DP 11 [ i + 11 ] = Ø \\ DP 11 [ i + 12 ] = Ø \\ DP 11 [ i + 13 ] = Ø \\ DP 11 [ i + 14 ] = Ø \\ DP 11 [ i + 15 ] = Ø\end{matrix} & ( 21 ) \\ DP 12 = \{ \begin{matrix}DP 12 [ i ] = {d}_{i + 6} ⊕ {d}_{i + 5} ⊕ {d}_{i + 4} \\ DP 12 [ i + 1 ] = {d}_{i + 7} ⊕ {d}_{i + 6} ⊕ {d}_{i + 5} \\ DP 12 [ i + 2 ] = {d}_{i + 7} ⊕ {d}_{i + 6} ⊕ {d}_{i + 5} \\ DP 12 [ i + 3 ] = {d}_{i + 7} ⊕ {d}_{i + 6} ⊕ {d}_{i + 4} \\ DP 12 [ i + 4 ] = {d}_{i + 7} ⊕ {d}_{i + 6} \\ DP 12 [ i + 5 ] = {d}_{i + 7} ⊕ {d}_{i + 5} \\ DP 12 [ i + 6 ] = {d}_{i + 7} \\ DP 12 [ i + 7 ] = {d}_{i + 6} ⊕ {d}_{i + 4} \\ DP 12 [ i + 8 ] = {d}_{i + 4} \\ DP 12 [ i + 9 ] = {d}_{i + 7} ⊕ {d}_{i + 5} ⊕ {d}_{i + 4} \\ DP 12 [ i + 10 ] = {d}_{i + 5} \\ DP 12 [ i + 11 ] = {d}_{i + 6} ⊕ {d}_{i + 5} \\ DP 12 [ i + 12 ] = {d}_{i + 6} \\ DP 12 [ i + 13 ] = {d}_{i + 7} ⊕ {d}_{i + 6} \\ DP 12 [ i + 14 ] = {d}_{i + 7} \\ DP 12 [ i + 15 ] = {d}_{i + 7} \end{matrix} & ( 22 )\end{matrix}$$

Symbol Ø means that no XOR operation should be executed between the corresponding bits of DP11 and DP12 during the execution of XOR operations according to relation (20).

Sub-systems DP11 and DP12 can be pre-computed for each value of the set of bits {dᵢ; . . . ; dᵢ₊₃} and {dᵢ₊₄; . . . ; dᵢ₊₇}, respectively and the results stored in lookup tables DP11 and DP12. Lookup tables DP11 and DP12 store 2⁴×8 and 2⁴×16 bits respectively. Thus, the total number of bits stored in lookup tables DP11 and DP12 is smaller than the number of bits stored in lookup table DP1.

What has been illustrated in the particular case of sub-system DP1 and lookup table DP1 can be applied to any of the sub-systems disclosed herein above such as sub-systems DP11. The smaller memory space necessary to implement one of the above encoding channel methods is achieved when each system has been split up into a succession of sub-systems, the value of each of these sub-systems depending only on the value of a set of two bits. However, in this situation, it is necessary to carry out a large number of XOR operations between the result of each sub-system to obtain the encoded bit stream. In fact, the number of operations to be executed by the processor proportionally increases with the number of lookup tables used.

At the end of turbo encoding, switches 36 and 66 are switched to connect the outputs of XOR gates 28 and 58 to the second input of XOR gates 34 and 64 respectively. This configuration of encoder 2 can be modeled using a system of parallel XOR operations and utilized on microprocessor 92. Preferably, the implementation of the end of the turbo encoding is carried out using several smaller lookup tables than the one corresponding to the whole modeled system using the teaching disclosed herein above.

The above teaching applies to any channel encoder corresponding to a hardware implementation having a shift register and XOR gates. It also applies to any channel encoder used in other standards such as, for example, the WMAN (Wireless Metropolitan Area Network) or other standards in wireless communications.

The channel encoding method has been described in the particular case where a block of 5 bits is inputted in the processor at each iteration of the method. The method can be generalized to other sizes of inputted bit blocks, such as, to blocks having 8, 16 or 32 bits for example.

The above channel encoding method can be implemented in any type of user equipment as well as in a base station.

1. A channel encoding method of calculating, using a programmable processor, a code identical with a code obtained with a hardware channel encoder comprising,
reading the result of a first sub-system of parallel XOR operations between shifted bits in a first pre-computed lookup table at a memory address determined from the value of the inputted bits, the first pre-computed lookup table storing any possible result of the first sub-system at respective memory addresses; and
carrying out an XOR operation between the read result and the result of a second sub-system of parallel XOR operations using the XOR instruction of the programmable processor.

2. The method according to claim 1, wherein the method further comprises reading the result of the second sub-system in a second pre-computed lookup table at an address determined from the value of the inputted bits, the second pre-computed lookup table recording any possible result of the second sub-system at respective memory addresses.

3. The method according to claim 2 to calculate a code identical with a code obtained with a hardware convolutional encoder, wherein the memory addresses used during the first and second reading steps are only determined from the values of two successive sets of inputted bits.

4. The method according to claim 3 of calculating a code identical with a code obtained with a hardware channel encoder having at least a feedback chain, the set of bits stored in the shift register being called a remainder, wherein the address used during one of the reading steps is only determined from the current value of the remainder.

5. The method according to claim 1, the hardware channel encoder corresponding to a system of XOR operations having N relations between P variables linked to each other by XOR operations, each relation being designed to provide the value of one bit of the code, wherein each sub-system corresponds to a part of the system comprising a number of variables strictly smaller than the number P.

6. The method according to claim 1 of calculating a code identical with a code obtained with a hardware channel encoder, the channel encoder comprising:
at least two forward chains to output bits; and
a multiplexer to carry out multiplexing operations of the output of each forward chain, wherein the result recorded in each of the lookup tables also utilizes the multiplexing operation.

7. A memory comprising instructions to execute a channel encoding method according to claim 1, when the instructions are executed by a programmable processor.

8. A microprocessor program comprising instructions to execute a channel encoding method according to claim 1, when the instructions are executed by a programmable processor.

9. A channel encoder adapted to carry out a channel encoding method according to claim 1, the channel encoder comprising:
a programmable processor adapted to execute an XOR operation in response to an XOR instruction; and
a memory connected to the processor,
wherein the memory comprises the first pre-computed lookup table which stores the results of the first sub-system, and wherein the processor is adapted to read the result of the first sub-system in the first pre-computed lookup table, and to carry out an XOR operation between the read result and the result of the second sub-system of XOR operations using the XOR instruction of the programmable processor.

10. A channel encoder according to claim 9, wherein the memory comprises the second pre-computed lookup table which stores the results of the second sub-system, and wherein the processor is adapted to read the result of the second sub-system in the second pre-computed lookup table.

11. User equipment, comprising a channel encoder according to claim 9.

12. A base station comprising a channel encoder according to claim 9.
